(19) United States
(12) Patent Application Publication
(10) Pub. No.: US 2024/0422892 A1
(43) Pub. Date: Dec. 19, 2024

(54) HEAT SPREADERS FEATURING COEFFICIENT OF THERMAL EXPANSION MATCHING AND HEAT DISSIPATION USING SAME

(71) Applicant: Kuprion Inc., Waterbury, CT (US)

(72) Inventor: Alfred A. Zinn, Palo Alto, CA (US)

(21) Appl. No.: 18/706,411

(22) PCT Filed: Nov. 17, 2022
(86) PCT No.: PCT/US2022/080001

§ 371 Date: May 1, 2024

Related U.S. Application Data
(60) Provisional application No. 63/280,694, filed on Nov. 18, 2021.

(51) Int. Cl. H05K 1/02

(52) U.S. Cl. CPC H05K 1/0203; H05K 2201/068

(57) ABSTRACT

Heat spreaders may be tailored for coefficient of thermal expansion (CTE) matching with electronic components or other heat-producing components in thermal communication therewith. In some cases, the heat-producing component may be bonded to the heat spreader while realizing the CTE matching. Copper nanoparticles may be consolidated under mild conditions with a CTE modifier to define a heat spreader configured for contacting a heat source and a heat sink, in which at least a portion of the heat spreader comprises a copper composite comprising the CTE modifier. The copper composite may be present in a thermally conductive body or a coating thereon that defines the heat spreader. The copper composite may contact a heat-producing component for promoting effective heat transfer and robust bonding between the two, such as within a printed circuit board (PCB), followed by dissipation of the heat to a heat sink or other heat-receiving structure.

### BACKGROUND

Ineffective thermal communication between a heat source and a heat sink can hamper dissipation of excess heat from a system, especially within electronic devices. Heat-generating electronic components, such as high-power LEDs and high-power circuitry, for example, are continually decreasing in size and becoming ever more powerful, thereby generating loads of excess heat that are increasingly being concentrated in smaller and smaller spaces. Increasing levels of integration in system in package (SIP) systems and complex electronics packing may also make heat dissipation difficult. Growing production of excess heat and concentration thereof can make effective heat removal important yet especially problematic. Failure to remove excess heat from an electronic system can result in significant consequences such as, for example, overheating, reduced conduction, higher power requirements than normal, and/or the need for clock-down operation to avoid board burnout and device failure due to the presence of hot spots. Failure modes may include lateral displacement forces resulting from coefficient of thermal expansion (CTE) mismatch, which may exceed the strength of bond lines and lead to breaking of circuits and/or shorting.

Ineffective heat conduction can be especially prevalent in circuit boards of various types, particularly printed circuit boards (PCBs), complex packaging, stacked boards, and system in package (SIP) components. PCBs and similar circuit boards are thermal insulators by the very nature of their construction. Specifically, PCBs may employ thermally insulating substrates (e.g., glass fiber epoxy composites like FR4, a common example, which has a thermal conductivity value of only 0.25 W/m·K), upon which appropriate electronic circuitry and various board components are disposed. The low thermal conductivity values of PCB substrates can make removal of excess heat from electronic systems rather difficult. Very little excess heat is capable of being removed via the leads or embedded metal traces due to their typically small size. In addition, conventional lead solder is not especially thermally conductive (e.g., about 1/10^{th} or less than that of more thermally conductive metals, such as copper). Package substrates having heat slugs for GaN and SiC devices, monolithic microwave integrated circuits (MMICs), phased arrays, and the like, such as those found in 5G base stations and power converters, for example, may experience similar issues. EMI shielding may experience related issues but without the occurrence of shorting.

Thermal vias are one approach for removing excess heat generated by an electronic component associated with a printed circuit board or similar structure. However, direct liquid casting of high-melting metals into vias is not compatible with the board materials that are presently in use (metal processing temperatures >1000° C. in comparison to much lower polymer melting points for materials typically used as PCB substrates). As such, vias are often packed with rosin or a similar filler and then galvanically capped at the ends or left open, with just a thick metal plating (e.g., copper) formed on the via walls (i.e., the via barrel) to promote electrical communication through the PCB substrate. This approach takes place by slow electrodeposition and may afford sub-optimal thermal communication by leaving gaps in a metal plug extending through the PCB. An alternative approach for filling vias using metal nanoparticles is described in U.S. Pat. No. 10,616,994, incorporated herein by reference, which may promote more complete filling of via holes and afford higher thermal conductivity. Large-diameter vias may be compatible with such processes to provide more effective removal of excess heat. For removing large quantities of excess heat, even thermal vias may be insufficient.

Thermal coins are another approach for heat dissipation that may be used when more thermal conduction is needed than can be provided by thermal vias. Thermal coins are metal bodies 3-4 mm in diameter that are pressed into the plane of a PCB or similar substrate. Although increased thermal conduction relative to thermal vias may result, size misfits are common, and the thicknesses of the PCB during production and the prefabricated thermal coins may vary, which may cause assembly issues when stacking multiple PCB layers together. Thermal coins are also usually manufactured in a limited range of shapes, which may not be applicable to a particular PCB architecture.

Heat pipes are an alternative heat transfer medium that may facilitate transfer of exceedingly large quantities of excess heat. Whereas highly thermally conductive metals, such as copper, may have thermal conductivity values only in the hundreds of W/m·K range, heat pipes may offer much higher effective thermal conductivity values, into the thousands of W/m·K range, such as about 10,000 W/m·K to about 100,000 W/m·K. Heat pipes function through direct heat transfer to a working fluid housed within a sealed vessel, wherein conduction is further supplemented by a liquid-vapor phase transition and subsequent condensation of the working fluid. Heat pipes have traditionally been utilized in applications where passive dissipation of heat in rugged operating environments is desirable. Examples include satellites and spacecraft applications. Miniaturized heat pipes, such as oscillating heat pipes, have recently been used to dissipate excess heat from printed circuit boards and similar small heat-producing electronic components.

Like heat pipes, heat spreaders may also promote dissipation of excess heat from a heat source in contact therewith. Heat spreaders lack the working fluid of heat pipes and instead may promote lateral spreading of heat through a monolithic, thermally conductive body to promote more effective rejection of the excess heat to a thermal reservoir. Heat spreaders may be tapered to promote dissipation of excess heat from a heat source having limited size, including point-like sources, to a dissipation surface spread over a larger area, commonly at or adjacent to a heat sink.

A difficulty associated with both heat pipes and heat spreaders is that there may be ineffective thermal communication between a heat-producing component and an outer surface of the heat pipe or heat spreader due to coefficient of thermal expansion (CTE) mismatch. Copper, for instance, is a highly thermally conductive metal often utilized for forming the outer shell of heat pipes or for forming a monolithic metal body of heat spreaders, but this metal differs considerably in CTE from the ceramic materials commonly present in heat-producing components of printed circuit boards or similar components generating excess heat. The CTE mismatch may lead to disengagement of a heat-producing component from a heat pipe or heat spreader as heating occurs, thereby significantly negating the ability of the heat pipe or heat spreader to dissipate excess heat from the heat-producing component. Heat spreader disengagement from a heat sink or other heat-receiving structure may be similarly problematic. Moreover, materials used for bonding a heat pipe or heat spreader to a heat-producing component may further contribute to the CTE mismatch as well.

### BRIEF DESCRIPTION OF THE DRAWINGS

The following figures are included to illustrate certain aspects of the present disclosure, and should not be viewed as exclusive embodiments. The subject matter disclosed is capable of considerable modifications, alterations, combinations, and equivalents in form and function, as will occur to one having ordinary skill in the art and the benefit of this disclosure.

FIGS. 1 and 2 show diagrams of presumed structures of metal nanoparticles having a surfactant coating thereon.

FIGS. 3A-3D show cross-sectional diagrams of various configurations of heat spreaders of the present disclosure.

FIG. 4 shows a diagram of an illustrative heat spreader in which a plurality of conductive fibers extend from a coating at one end of a thermally conductive body.

FIG. 5 shows a diagram in which a heat spreader is bonded to a top surface of a heat-producing component.

FIG. 6 shows a diagram in which a heat spreader is bonded to a bottom surface of a heat-producing component.

FIG. 7 shows a diagram in which heat spreaders are bonded to a top surface and a bottom surface of a heat-producing component.

FIG. 8 shows a diagram in which multiple heat spreaders are bonded to a side surface of a heat-producing component.

### DETAILED DESCRIPTION

The present disclosure is generally directed to thermal management and, more specifically, to heat spreaders having at least an outer surface with improved coefficient of thermal expansion (CTE) matching to heat-producing components employed in printed circuit boards (PCBs) and related electronic systems, including copper cladded boards (CCBs) and boards employing emerging ceramics like AlN and SiN. The heat-producing component may employ an electrically and thermally insulating substrate like FR4 or other polymeric substrate, or substrates that are electrically insulating but thermally conductive, such as AlN, may be employed in some instances. Advantageously, the present disclosure may facilitate tailoring the CTE of at least the outer surface of the heat spreader to match the CTE of a given heat-producing component. CTE matching to that of a heat sink or similar heat-receiving structure may also be realized. The heat spreader may be directly attached to the backside of a PCB as a monolithic thermal ground plane or as a finned heat sink. Direct metal bonding may be realized in some system architectures employing a bonding layer between the heat spreader and the heat-producing component, thereby resulting in mechanical robustness. Moreover, the heat spreaders and related concepts of the present disclosure may avoid or minimize the use of thermal greases and gel pads, which otherwise may be necessary to mitigate CTE mismatch, albeit at the cost of less effective thermal conductivity. Tailoring of the CTE may be accomplished in various manners described hereinafter.

As discussed above, removal of excess heat from heat-producing components of circuit boards and related electronics assemblies can be problematic due to the prevalence of thermally insulating materials therein. Heat spreaders may be effective for dissipating large amounts of excess heat from such systems, but CTE mismatch between metallic components of heat spreaders and various portions of electronic components or other heat-producing constructs may be significant, particularly those containing non-metallic components, such as various ceramics. CTE mismatch may be prevalent in heat-producing components featuring both thermally insulating and thermally conductive substrates, such as AlN and SiN. If excessive CTE mismatch is present in either type of system, a heat spreader may disconnect from a heat-producing component upon being heated, thereby negating or severely limiting the ability of the heat spreader to dissipate excess heat and resulting in overheating and burn-out of the heat-producing component.

The present disclosure provides heat spreaders that may afford more effective CTE matching between at least an outer surface of the heat spreader and a heat-producing component. More particularly, the present disclosure provides metal composites comprising a CTE modifier, such as a copper composite, which may define at least an outer surface of a heat spreader, and optionally a larger portion or even the entirety of a heat spreader. The metal composites may be formed using metal nanoparticles, such as copper nanoparticles, that have undergone consolidation with one another to form bulk metal having a low degree of nanoporosity. Even before CTE modification, fused copper nanoparticles have a relatively low CTE of only about 7-11 ppm (varies based on the degree of nanoporosity present), which may be further adjusted in a copper composite using at least one CTE modifier as described further herein. The CTE of the metal composite may be readily modified by adjusting the loading of the CTE modifier in a continuous metal matrix to promote more effective CTE matching with ceramic materials in a heat-producing component, such as those containing SiC, GaN, AlN, and the like. The metal composites may be formed readily from compositions comprising metal nanoparticles, such as copper nanoparticles, which may allow the metal composites and heat spreaders to be formed at low temperatures via solid-state sintering, well below the melting point of molten metals. A heat sink or similar heat-receiving structure may be similarly CTE matched to the heat spreader by utilizing metal nanoparticles and the CTE modifier in that location as well. Additional details regarding metal nanoparticles, such as copper nanoparticles, and the properties that may facilitate low-temperature processing thereof are described hereinbelow.

Suitable CTE modifiers may decrease the already-low CTE of a bulk metal formed from copper nanoparticles (7-11 ppm) down to as low as 3 ppm in some cases at room temperature, as compared to a value of 17 ppm typically found for bulk copper. These features may greatly simplify PCB assembly and other heat-transfer architectures and provide overall product cost reduction while significantly enhancing performance and reliability in locations where severe thermal shock and significant thermal cycling occurs. By the same token, the CTE may be adjusted upward by including bulk copper powder during copper nanoparticle consolidation, including CTE values approaching as much as 17 ppm. Even higher CTE values may be realized, if needed, by including micron-size particles of other metals, such as aluminum particles, flakes or wires, in which case CTE values approaching 23 ppm may be realized. Accordingly, metal composites of the present disclosure may be formed from copper nanoparticles and at least one CTE modifier, optionally in further combination with bulk copper powder, to afford a range of accessible CTE values.

In addition to facilitating improved CTE matching between a heat spreader and a substrate of an electronic component or similar heat-producing component, the metal nanoparticle compositions may also promote direct bonding between the electronic component and the heat spreader by way of a bonding layer, similar to that produced by soldering or use of a metal paste. For example, the metal nanoparticle compositions may be applied upon the surface of an electronic component as a bonding layer, wherein subsequent consolidation of the metal nanoparticles within the bonding layer may facilitate direct metallurgical bonding to at least a portion of an outer surface of the heat spreader also formed from consolidated metal nanoparticles. The direct metallurgical bonding considerably lessens the likelihood of the heat-producing component and the heat spreader from becoming disengaged from one another. Moreover, because the heat spreader (or an outer coating thereof) and the bonding layer may be formed from similar materials, there is less likelihood of CTE mismatch occurring, thereby limiting or even eliminating thermomechanical stress. That is, the bonding layer may define a transition layer having a CTE intermediate between the electronic component and the outer surface of the heat spreader. At large electronic component sizes and high operating temperatures (e.g., up to about 350° C.), even small CTE differences may otherwise result in high thermomechanical stress values, leading to potential delamination and device failure. CTE matching of the outer surface of the heat spreader to a heat sink or similar heat-receiving structure may similarly be realized using metal nanoparticles and a CTE modifier to form at least a portion of the heat sink or similar heat-receiving structure, with metallurgical bonding occurring in some cases.

The heat spreaders of the present disclosure may be utilized in conjunction with printed circuit boards and similar architectures in which a heat-producing electronic component is problematic. The heat spreaders may be connected to the printed circuit boards and similar architectures in various manners. A heat-producing component located upon or recessed within a face of the printed circuit board may be connected to a heat spreader of the present disclosure on a front face facing away from a non-conductive substrate of a PCB, on sides of the heat-producing electronic component, and/or on an underside of the heat-producing electronic component. In the latter configuration, the heat spreader may extend through the electrically insulating substrate of the PCB to contact the heat-producing component. Combinations of the foregoing heat spreader configurations may be used to provide multiple heat transfer pathways. The foregoing heat spreader configurations for connecting a heat spreader to a heat-producing component may be utilized to facilitate stacking of multiple printed circuit board layers upon one another to afford 3-D integration of devices and systems, such as SIPs and memory devices on top of a processor. The heat spreader may be in thermal communication with a structure for rejecting excess heat shunted therethrough, such as a liquid reservoir, radiator, or like structure functioning as a heat sink. A heat spreader may be in further thermal communication or physical contact with a heat pipe in some instances, wherein the heat pipe may convey the excess heat even further away from the heat-producing electronic component. That is, a heat pipe may intervene between the heat spreader and a heat sink in some cases.

Similarly, in the case of a heat-producing component featuring electrically insulating but highly thermally conductive substrates, such as AlN or SiN, the heat spreaders of the present disclosure may be located upon either face of the substrate, or may be at least partially located internally within the substrate. When an electrically insulating but thermally conductive substrate is used, the heat spreader may be in thermal communication with the heat-producing component by way of the thermally conductive substrate rather than contacting the heat-producing component directly. In some cases, the AlN or SiN may be deposited as a thin film (e.g., about 300 microns to about 500 microns in thickness) upon the surface of an electrically insulating substrate to convey thermal conductivity thereto. Heat spreaders of the present disclosure may also be used in these configurations as well.

Metal nanoparticles are uniquely qualified for forming at least a surface coating upon a heat spreader, or optionally the entirety of a heat spreader. At the very least, the heat spreader may be better CTE matched to a heat-producing component having a low CTE, and if a bonding layer is further utilized, the bonding layer may afford a robust bonding interaction between the heat spreader and a heat-producing component or the bonding layer may have an intermediate CTE between that of the heat-producing component and the heat spreader. Moderate processing conditions for consolidating metal nanoparticles to form bulk metal (e.g., bulk copper) in a metal composite (e.g., a copper composite comprising a CTE modifier) having low nanoporosity may facilitate forming the bonding layer and other optional components of the heat spreader. As described in further detail below, metal nanoparticles can be consolidated (fused) together into the corresponding bulk metal under a range of mild processing conditions that are significantly below the melting point of the metal itself. Due to copper's high thermal conductivity and relatively low cost, copper nanoparticles can be a particularly desirable type of metal nanoparticle for use in the various embodiments of the present disclosure. Bulk copper formed from metal nanoparticles combined with a CTE modifier may effectively form a well-dispersed composite following metal nanoparticle consolidation. Suitable CTE modifiers may include, for example, carbon fibers, diamond particles, boron nitride particles or fibers, carbon nanotubes, graphene, W and/or Mo particles, silicon particles, graphite powder, silicon nitride particles or fibers, aluminum nitride particles or fibers, copper oxide nanoparticles, and any combination thereof. W and/or Mo particles may also convey oxidation resistance to copper. In addition to promoting CTE matching between the surface of the heat spreader and a heat-producing component, the CTE modifier and optional micron-sized metal particles may also limit shrinkage during consolidation of metal nanoparticles, which may otherwise exceed 20% in other metal nanoparticle systems. The limited shrinkage may help mitigate thermomechanical stress during operational hot-cold cycling encountered during use of heat spreaders. In addition, the nanoporosity resulting following metal nanoparticle consolidation may convey additional flexibility that may provide additional tolerance to thermomechanical stress.

In addition to the foregoing advantages, metal nanoparticles may facilitate production of heat spreaders having further enhanced structures for dissipating heat therefrom. For example, some heat spreaders of the present disclosure may comprise a plurality of thermally conductive fibers extending from an end portion of the heat spreader (the cool end), which may facilitate ready dissipation of excess heat to a heat sink, such as ambient atmosphere, a marine environment (e.g., sea, lake or river water), or a radiator for space applications. The conductive fibers may be bonded to the heat spreader using a metal nanoparticle composition also effective for promoting CTE matching, as described in brief above and in further detail hereinafter. Bonding of the conductive fibers may be accomplished during manufacturing of the heat spreader without a separately bonding step taking place by incorporating ends of the conductive fibers into a suitable metal nanoparticle composition prior to metal nanoparticle consolidation taking place. Following consolidation of the metal nanoparticles, one set of the ends of the conductive fibers remain firmly fixed in the resulting metal composite and the other set of the ends of the conductive fibers extend outwardly from the heat spreader to promote heat dissipation therefrom.

As used herein, the term “metal nanoparticle” refers to metal particles that are about 200 nm or less in size, without particular reference to the shape of the metal particles.

As used herein, the term “micron-scale metal particles” refers to metal particles that are about 200 nm or greater in size in at least one dimension.

The terms “consolidate,” “consolidation” and other variants thereof are used interchangeably herein with the terms “fuse,” “fusion” and other variants thereof.

As used herein, the terms “partially fused,” “partial fusion,” and other derivatives and grammatical equivalents thereof refer to the partial coalescence of metal nanoparticles with one another. Whereas totally fused metal nanoparticles retain only minimal structural morphology of the original unfused metal nanoparticles (i.e., they resemble a dense bulk metal, but exhibit internal grain sizes in the 100-500 nm range with a low degree of nanoporosity), partially fused metal nanoparticles retain at least some of the structural morphology of the original unfused metal nanoparticles, such as a higher level of porosity, a smaller average grain size, and a higher number of grain boundaries. The properties of partially fused metal nanoparticles can be intermediate between those of the corresponding bulk metal and the original unfused metal nanoparticles. In some embodiments, fully dense (non-porous) bulk metal can be obtained following metal nanoparticle consolidation to afford a metal composite. In other embodiments, metal composites may have less than about 10% porosity, or less than about 20% porosity, or less than about 30% porosity in an amount above full densification (i.e., >0% porosity). Thus, in particular embodiments, a metal composite formed from metal nanoparticles and a CTE modifier may have a porosity (nanoporosity) ranging from about 2% to about 30%, or about 2% to about 5%, or about 5% to about 10%, or about 10% to about 15%, or about 15% to about 20%, or about 20% to about 25%, or about 25% to about 30%.

Before further discussing more particular aspects of the present disclosure in more detail, additional brief description of metal nanoparticles and their processing conditions, particularly copper nanoparticles, will first be provided. Metal nanoparticles exhibit a number of properties that can differ significantly from those of the corresponding bulk metal. One property of metal nanoparticles that can be of particular importance for processing according to the disclosure herein is nanoparticle fusion (consolidation) that occurs at the metal nanoparticles' fusion temperature. As used herein, the term “fusion temperature” refers to the temperature at which a metal nanoparticle liquefies, thereby giving the appearance of melting. As used herein, the terms “fusion” and “consolidation” synonymously refer to the coalescence or partial coalescence of metal nanoparticles with one another to form a larger mass, such as a bonding interface or metal composite upon at least the outer surface of a heat spreader. The fusion temperature may be as much as 80% below the melting point of the corresponding bulk metal. Accordingly, there is at least partial connectivity between the metal nanoparticles following heating above the fusion temperature. Following consolidation of the metal nanoparticles, the resulting nanoporosity may accommodate thermal stresses occurring during heat and cooling cycles. Without being bound by theory or mechanism, the nanoporosity may absorb the stress resulting from expansion or contraction of a heat spreader, rather than undergoing failure from rapid release of the thermomechanical stress.

Upon decreasing in size, particularly below about 20 nm in equivalent spherical diameter, the temperature at which metal nanoparticles undergo liquefication drops dramatically from that of the corresponding bulk metal. For example, copper nanoparticles having a size of about 20 nm or less can have fusion temperatures of about 235° C. or below, or about 220° C. or below, or about 200° C. or below, in comparison to bulk copper's melting point of 1083° C. Thus, the consolidation of metal nanoparticles taking place at the fusion temperature can allow structures containing bulk metal to be fabricated at significantly lower processing temperatures than when working directly with the bulk metal itself as a starting material. Processing conditions for consolidating metal nanoparticles are typically within normal PCB manufacturing parameters of around 375° F. (190.6° C.), or even up to about 450° F. (232.2° C.), and 275-400 psi; however, pressure is not necessarily required for metal nanoparticle fusion to take place. More dense bulk metal may be obtained by applying pressure when promoting metal nanoparticle consolidation. Thus, pressures even up to about 1500 psi may be applied to the metal nanoparticles to promote consolidation in some cases. In the case of copper nanoparticles, for example, the fusion temperature (˜220° C. or less) is below the temperatures at which commonly used PCB substrates undergo melting or distortion. Fusion of copper nanoparticles may therefore take place in conjunction with the temperature conditions used in conventional PCB manufacturing processes, although more vigorous consolidation conditions may optionally be used. Fusion may take place under an inert atmosphere to preclude metal oxidation, or in the case of larger surfaces or articles, there may be sufficient outgassing to limit oxidation even in the absence of an inert atmosphere. Accordingly, metal nanoparticles, such as copper nanoparticles, provide a facile material for forming bulk metal of a metal composite within at least a portion of a heat spreader or a bonding layer upon a heat spreader, particularly when incorporating a heat spreader within a PCB manufacturing process.

A number of scalable processes for producing bulk quantities of metal nanoparticles in a targeted size range have been developed. Most typically, such processes for producing metal nanoparticles take place by reducing a metal precursor in the presence of one or more surfactants. The metal nanoparticles can then be isolated and purified from the reaction mixture by common isolation techniques and processed into a formulation suitable for dispensation.

Any suitable technique can be employed for forming the metal nanoparticles used in the disclosure herein. Particularly facile metal nanoparticle fabrication techniques are described in U.S. Pat. Nos. 7,736,414, 8,105,414, 8,192,866, 8,486,305, 8,834,747, 9,005,483, 9,095,898, and 9,700,940, each of which is incorporated herein by reference in its entirety. As described therein, metal nanoparticles can be fabricated in a narrow size range by reduction of a metal salt in a solvent in the presence of a suitable surfactant system, which can include one or more different surfactants. Targeted size distributions of metal nanoparticles, including bimodal size distributions, may be obtained by combining metal nanoparticles of different sizes together. Further description of suitable surfactant systems follows below. Without being bound by any theory or mechanism, it is believed that the surfactant system can mediate the nucleation and growth of the metal nanoparticles, limit surface oxidation of the metal nanoparticles, and/or inhibit metal nanoparticles from extensively aggregating with one another prior to being at least partially fused together. Suitable organic solvents for solubilizing metal salts and forming metal nanoparticles can include, for example, formamide, N,N-dimethylformamide, dimethyl sulfoxide, dimethylpropylene urea, hexamethylphosphoramide, tetrahydrofuran, glyme, diglyme, triglyme, tetraglyme, proglyme, or polyglyme. Reducing agents suitable for reducing metal salts and promoting the formation of metal nanoparticles can include, for example, an alkali metal in the presence of a suitable catalyst (e.g., lithium naphthalide, sodium naphthalide, or potassium naphthalide) or borohydride reducing agents (e.g., sodium borohydride, lithium borohydride, potassium borohydride, or tetraalkylammonium borohydrides).

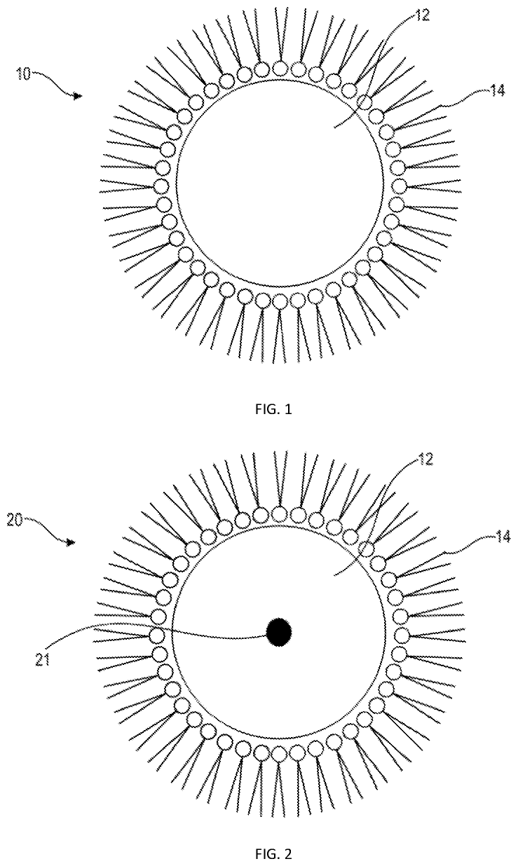

FIGS. 1 and 2 show diagrams of presumed structures of metal nanoparticles having a surfactant coating thereon. As shown in FIG. 1, metal nanoparticle 10 includes metallic core 12 and surfactant layer 14 overcoating metallic core 12. Surfactant layer 14 can contain any combination of surfactants, as described in more detail below. Metal nanoparticle 20, shown in FIG. 2, is similar to that depicted in FIG. 1, except metallic core 12 is grown about nucleus 21, which can be a metal that is the same as or different than that of metallic core 12. Because nucleus 21 is buried deep within metallic core 12 in metal nanoparticle 20 and is very small in size, it is not believed to significantly affect the overall nanoparticle properties. Nucleus 21 may comprise a salt or a metal, wherein the metal may be the same as or different than metallic core 12. In some embodiments, the nanoparticles can have an amorphous morphology.

As discussed above, the metal nanoparticles have a surfactant coating containing one or more surfactants upon their surface. The surfactant coating can be formed on the metal nanoparticles during their synthesis. The surfactant coating is generally lost during consolidation of the metal nanoparticles upon heating above the fusion temperature, which results in formation of bulk metal, possibly having uniform nanoporosity present therein. Formation of a surfactant coating upon metal nanoparticles during their syntheses can desirably limit the ability of the metal nanoparticles to fuse to one another prematurely, limit agglomeration of the metal nanoparticles, and promote the formation of a population of metal nanoparticles having a narrow size distribution. Porosity values may range from about 2-30% or about 2-15% following consolidation, which may be tailored based upon a number of factors, including the type of surfactant(s) that are present and whether micron-scale metal particles are contacted with the metal nanoparticles during consolidation. At about 2% to about 15% nanoporosity, a copper composite may comprise about 85%-98% dense fused copper nanoparticles with closed pore nanoporosity having a pore size ranging from about 50 nm to about 500 nm, or about 100 nm to about 300 nm, or about 150 nm to about 250 nm.

The types of metal nanoparticles suitable for use in conjunction with the various embodiments of the present disclosure are not believed to be particularly limited. Suitable metal nanoparticles can include, but are not limited to, tin nanoparticles, copper nanoparticles, aluminum nanoparticles, palladium nanoparticles, silver nanoparticles, gold nanoparticles, iron nanoparticles, cobalt nanoparticles, nickel nanoparticles, titanium nanoparticles, zirconium nanoparticles, hafnium nanoparticles, tantalum nanoparticles, molybdenum nanoparticles, tungsten nanoparticles, and the like. Combinations of these metal nanoparticles may be used as well. Micron-scale particles of these metals can be present in metal nanoparticle paste compositions containing the metal nanoparticles as well. Copper can be a particularly desirable metal for use in the embodiments of the present disclosure due to its low cost, strength, and excellent electrical and thermal conductivity values.

In various embodiments, the surfactant system present within the metal nanoparticles can include one or more surfactants. The differing properties of various surfactants can be used to tailor the properties of the metal nanoparticles. Factors that can be taken into account when selecting a surfactant or combination of surfactants for inclusion upon the metal nanoparticles can include, for example, ease of surfactant dissipation from the metal nanoparticles during nanoparticle fusion, nucleation and growth rates of the metal nanoparticles, the metal component of the metal nanoparticles, and the like.

In some embodiments, an amine surfactant or combination of amine surfactants, particularly aliphatic amines, can be present upon the metal nanoparticles. Amine surfactants can be particularly desirable for use in conjunction with copper nanoparticles. In some embodiments, two amine surfactants can be used in combination with one another. In other embodiments, three amine surfactants can be used in combination with one another. In more specific embodiments, a primary amine, a secondary amine, and a diamine chelating agent can be used in combination with one another. In still more specific embodiments, the three amine surfactants can include a long chain primary amine, a secondary amine, and a diamine having at least one tertiary alkyl group nitrogen substituent. Further disclosure regarding suitable amine surfactants follows hereinafter.

In some embodiments, the surfactant system can include a primary alkylamine. In some embodiments, the primary alkylamine can be a C₂-C₁₈ alkylamine. In some embodiments, the primary alkylamine can be a C₇-C₁₀ alkylamine. In other embodiments, a C₅-C₆ primary alkylamine can also be used. Without being bound by any theory or mechanism, the exact size of the primary alkylamine can be balanced between being long enough to provide an effective inverse micelle structure during synthesis versus having ready volatility and/or ease of handling during nanoparticle consolidation. For example, primary alkylamines with more than 18 carbons can also be suitable for use in the present embodiments, but they can be more difficult to handle because of their waxy character. C₇-C₁₀ primary alkylamines, in particular, can represent a good balance of desired properties for ease of use.

In some embodiments, the C₂-C₁₈ primary alkylamine can be n-hexylamine, n-heptylamine, n-octylamine, n-nonylamine, or n-decylamine, for example. While these are all straight chain primary alkylamines, branched chain primary alkylamines can also be used in other embodiments. For example, branched chain primary alkylamines such as, for example, 7-methyloctylamine, 2-methyloctylamine, or 7-methylnonylamine can be used. In some embodiments, such branched chain primary alkylamines can be sterically hindered where they are attached to the amine nitrogen atom. Non-limiting examples of such sterically hindered primary alkylamines can include, for example, t-octylamine, 2-methylpentan-2-amine, 2-methylhexan-2-amine, 2-methylheptan-2-amine, 3-ethyloctan-3-amine, 3-ethylheptan-3-amine, 3-ethylhexan-3-amine, and the like. Additional branching can also be present. Without being bound by any theory or mechanism, it is believed that primary alkylamines can serve as ligands in the metal coordination sphere but be readily dissociable therefrom during metal nanoparticle consolidation.

In some embodiments, the surfactant system can include a secondary amine. Secondary amines suitable for forming metal nanoparticles can include normal, branched, or cyclic C₄-C₁₂ alkyl groups bound to the amine nitrogen atom. In some embodiments, the branching can occur on a carbon atom bound to the amine nitrogen atom, thereby producing significant steric encumbrance at the nitrogen atom. Suitable secondary amines can include, without limitation, dihexylamine, diisobutylamine, di-t-butylamine, dineopentylamine, di-t-pentylamine, dicyclopentylamine, dicyclohexylamine, and the like. Secondary amines outside the C₄-C₁2 range can also be used, but such secondary amines can have undesirable physical properties such as low boiling points or waxy consistencies that can complicate their handling.

In some embodiments, the surfactant system can include a chelating agent, particularly a diamine chelating agent. In some embodiments, one or both of the nitrogen atoms of the diamine chelating agent can be substituted with one or two alkyl groups. When two alkyl groups are present on the same nitrogen atom, they can be the same or different. Further, when both nitrogen atoms are substituted, the same or different alkyl groups can be present. In some embodiments, the alkyl groups can be C₁-C₆ alkyl groups. In other embodiments, the alkyl groups can be C₁-C₄ alkyl groups or C₃-C₆ alkyl groups. In some embodiments, C₃ or higher alkyl groups can be straight or have branched chains. In some embodiments, C₃ or higher alkyl groups can be cyclic. Without being bound by any theory or mechanism, it is believed that diamine chelating agents can facilitate metal nanoparticle formation by promoting nanoparticle nucleation.

In some embodiments, suitable diamine chelating agents can include N,N′-dialkylethylenediamines, particularly C₁-C₄ N,N′-dialkylethylenediamines. The corresponding methylenediamine, propylenediamine, butylenediamine, pentylenediamine or hexylenediamine derivatives can also be used. The alkyl groups can be the same or different. C₁-C₄ alkyl groups that can be present include, for example, methyl, ethyl, propyl, and butyl groups, or branched alkyl groups such as isopropyl, isobutyl, s-butyl, and t-butyl groups. Illustrative N,N′-dialkylethylenediamines that can be suitable for inclusion upon metal nanoparticles include, for example, N,N′-di-t-butylethylenediamine, N,N′-diisopropylethylenediamine, and the like.

In some embodiments, suitable diamine chelating agents can include N,N,N′,N′-tetraalkylethylenediamines, particularly C₁-C₄ N,N,N′,N′-tetraalkylethylenediamines. The corresponding methylenediamine, propylenediamine, butylenediamine, pentylenediamine or hexylenediamine derivatives can also be used. The alkyl groups can again be the same or different and include those mentioned above. Illustrative N,N,N′,N′-tetraalkylethylenediamines that can be suitable for use in forming metal nanoparticles include, for example, N,N,N′,N′-tetramethylethylenediamine, N,N,N′,N′-tetraethylethylenediamine, and the like.

Surfactants other than aliphatic amines can also be present in the surfactant system. In this regard, suitable surfactants can include, for example, pyridines, aromatic amines, phosphines, thiols, or any combination thereof. These surfactants can be used in combination with an aliphatic amine, including those described above, or they can be used in a surfactant system in which an aliphatic amine is not present. Further disclosure regarding suitable pyridines, aromatic amines, phosphines, and thiols follows below.

Suitable aromatic amines can have a formula of ArNR¹R², where Ar is a substituted or unsubstituted aryl group and R¹ and R² are the same or different. R¹ and R² can be independently selected from H or an alkyl or aryl group containing from 1 to about 16 carbon atoms. Illustrative aromatic amines that can be suitable for use in forming metal nanoparticles include, for example, aniline, toluidine, anisidine, N,N-dimethylaniline, N,N-diethylaniline, and the like. Other aromatic amines that can be used in conjunction with metal nanoparticles can be envisioned by one having ordinary skill in the art.

Suitable pyridines can include both pyridine and its derivatives. Illustrative pyridines that can be suitable for use inclusion upon metal nanoparticles include, for example, pyridine, 2-methylpyridine, 2,6-dimethylpyridine, collidine, pyridazine, and the like. Chelating pyridines such as bipyridyl chelating agents may also be used. Other pyridines that can be used in conjunction with metal nanoparticles can be envisioned by one having ordinary skill in the art.

Suitable phosphines can have a formula of PR₃, where R is an alkyl or aryl group containing from 1 to about 16 carbon atoms. The alkyl or aryl groups attached to the phosphorus center can be the same or different. Illustrative phosphines that can be present upon metal nanoparticles include, for example, trimethylphosphine, triethylphosphine, tributylphosphine, tri-t-butylphosphine, trioctylphosphine, triphenylphosphine, and the like. Phosphine oxides can also be used in a like manner. In some embodiments, surfactants that contain two or more phosphine groups configured for forming a chelate ring can also be used. Illustrative chelating phosphines can include 1,2-bisphosphines, 1,3-bisphosphines, and bis-phosphines such as BINAP, for example. Other phosphines that can be used in conjunction with metal nanoparticles can be envisioned by one having ordinary skill in the art.

Suitable thiols can have a formula of RSH, where R is an alkyl or aryl group having from about 4 to about 16 carbon atoms. Illustrative thiols that can present upon metal nanoparticles include, for example, butanethiol, 2-methyl-2-propanethiol, hexanethiol, octanethiol, benzenethiol, and the like. In some embodiments, surfactants that contain two or more thiol groups configured for forming a chelate ring can also be used. Illustrative chelating thiols can include, for example, 1,2-dithiols (e.g., 1,2-ethanethiol) and 1,3-dithiols (e.g., 1,3-propanethiol). Other thiols that can be used in conjunction with metal nanoparticles can be envisioned by one having ordinary skill in the art.

As mentioned above, a distinguishing feature of metal nanoparticles is their low fusion temperature, which may facilitate consolidation to form bulk metal within a metal composite according to the disclosure herein. In order to facilitate their dispensation, the metal nanoparticles may be incorporated in a paste or similar formulation. Additional disclosure directed to metal nanoparticle paste compositions and similar formulations follows hereinbelow.

Metal nanoparticle paste compositions or similar formulations can be prepared by dispersing as-produced or as-isolated metal nanoparticles in an organic matrix containing one or more organic solvents and various other optional components. As used herein, the terms “nanoparticle paste formulation,” “nanoparticle paste composition,” “nanoparticle paste” and grammatical equivalents thereof are used interchangeably and refer synonymously to a fluid composition containing dispersed metal nanoparticles that is suitable for dispensation using a desired technique. Use of the term “paste” does not necessarily imply an adhesive function of the paste alone. Through judicious choice of the organic solvent(s) and other additives, the loading of metal nanoparticles and the like, ready dispensation of the metal nanoparticles and formation of bulk metal.

Cracking can sometimes occur during consolidation of the metal nanoparticles. One way in which the nanoparticle pastes of the present disclosure can promote a decreased degree of cracking and void formation following metal nanoparticle consolidation is by maintaining a high solids content. More particularly, in some embodiments, the paste compositions can contain at least about 30% metal nanoparticles by weight, particularly about 30% to about 98% metal nanoparticles by weight of the paste composition, or about 50% to about 95% metal nanoparticles by weight of the paste composition, or about 70% to about 98% metal nanoparticles by weight of the paste composition, or about 85% to about 98% by weight of the paste composition, or about 88% to about 99% by weight of the paste composition. Moreover, in some embodiments, small amounts (e.g., about 0.01% to about 15% or about 35% or about 60% by weight of the paste composition) of micron-scale particles, particularly micron-scale metal particles, can be present in addition to the metal nanoparticles. Micron-scale metal particles may encompass any of particulate materials, fibers and/or flakes. Such micron-scale metal particles can desirably promote the fusion of metal nanoparticles into a contiguous mass of bulk metal and further reduce the incidence of cracking. Instead of being liquefied and undergoing direct consolidation as is the case for the metal nanoparticles, the micron-scale metal particles can simply become joined together upon being contacted with liquefied metal nanoparticles that have been raised above their fusion temperature. These factors can reduce the porosity that results after fusing the metal nanoparticles together. The micron-scale metal particles can contain the same or different metals than the metal nanoparticles, and suitable metals for the micron-scale metal particles can include, for example, copper, silver, gold, aluminum, tin, molybdenum, tungsten, and the like. Micron-scale graphite particles may also be included, in some embodiments. Carbon nanotubes, boron nitride, diamond particles, and/or graphene may be included, in some embodiments. Carbonaceous additives may increase the thermal conductivity resulting after metal nanoparticle consolidation takes place, according to some embodiments. The micron-scale metal particles or similarly sized micron-scale additives may also function in the capacity of a CTE modifier. The loading of various CTE modifiers may further tailor the CTE for promoting CTE matching according to the disclosure herein. Any of the foregoing micron-scale particles may further serve as crack deflectors to limit propagation of cracks during use, thereby increasing mechanical strength.

Decreased cracking and void formation during metal nanoparticle consolidation can also be promoted by judicious choice of the solvent(s) forming the organic matrix. A tailored combination of organic solvents can desirably decrease the incidence of cracking and void formation. More particularly, an organic matrix containing one or more hydrocarbons (saturated, monounsaturated, polyunsaturated (2 or more double bonds) or aromatic), one or more alcohols, one or more amines, and one or more organic acids can be especially effective for this purpose. One or more esters and/or one or more anhydrides may be included, in some embodiments. Alkanolamines, such as ethanolamine, may also be present in some instances. Without being bound by any theory or mechanism, it is believed that this combination of organic solvents can facilitate the removal and sequestration of surfactant molecules surrounding the metal nanoparticles during consolidation, such that the metal nanoparticles can more easily fuse together with one another. More particularly, it is believed that hydrocarbon and alcohol solvents can passively solubilize surfactant molecules released from the metal nanoparticles by Brownian motion and reduce their ability to become re-attached thereto. In concert with the passive solubilization of surfactant molecules, amine and organic acid solvents can actively sequester the surfactant molecules through a chemical interaction such that they are no longer available for recombination with the metal nanoparticles.

Further tailoring of the solvent composition can be performed to reduce the suddenness of volume contraction that takes place during surfactant removal and metal nanoparticle consolidation. Specifically, more than one member of each class of organic solvent (i.e., hydrocarbons, alcohols, amines, and organic acids), optionally in combination with one or more alkanolamines, esters or anhydrides, can be present in the organic matrix, where the members of each class have boiling points that are separated from one another by a set degree. For example, in some embodiments, the various members of each class can have boiling points that are separated from one another by about 20° C. to about 50° C. By using such a solvent mixture, sudden volume changes due to rapid loss of solvent can be minimized during metal nanoparticle consolidation, since the various components of the solvent mixture can be removed gradually over a broad range of boiling points (e.g., about 50° C. to about 200° C.).

In various embodiments, at least some of the one or more organic solvents can have a boiling point of about 100° C. or greater. In other various embodiments, at least some of the one or more organic solvents can have a boiling point of about 200° C. or greater. In some or other embodiments, the one or more organic solvents can have boiling points ranging between about 50° C. and about 200° C., or between about 50° C. and about 250° C., or between about 50° C. and about 300° C., or between about 50° C. and about 350° C., or between about 50° C. and about 365° C. Use of high boiling organic solvents can desirably increase the pot life of the metal nanoparticle paste compositions and limit the rapid loss of solvent, which can otherwise lead to cracking and void formation during nanoparticle consolidation. In some embodiments, at least one of the organic solvents can have a boiling point that is higher than the boiling point(s) of the surfactant(s) associated with the metal nanoparticles. Accordingly, surfactant(s) can be removed from the metal nanoparticles by evaporation before removal of the organic solvent(s) takes place.

In some embodiments, the organic matrix can contain one or more alcohols, which may be C₂-C₁₂, C₄-C₁₂ or C₇-C₁₂ in more particular embodiments. In various embodiments, the alcohols can include monohydric alcohols, diols, or triols. One or more glycol ethers (e.g., diethylene glycol and triethylene glycol), alkanolamines (e.g., ethanolamine, triethanolamine, and the like), or any combination thereof may be present in certain embodiments, which may be present alone or in combination with other alcohols. Various glymes may be present with the one or more alcohols in some embodiments. In some embodiments, one or more hydrocarbons can be present in combination with one or more alcohols. As discussed above, it is believed that alcohol (and optionally glymes and alkanolamines) and hydrocarbon solvents can passively promote the solubilization of surfactants as they are removed from the metal nanoparticles by Brownian motion and limit their re-association with the metal nanoparticles. Moreover, hydrocarbon and alcohol solvents only weakly coordinate with metal nanoparticles, so they do not simply replace the displaced surfactants in the nanoparticle coordination sphere. Illustrative but non-limiting examples of alcohol and hydrocarbon solvents that can be present include, for example, light aromatic petroleum distillate (CAS 64742-95-6), hydrotreated light petroleum distillates (CAS 64742-47-8), tripropyleneglycol methyl ether, ligroin (CAS 68551-17-7, a mixture of C₁₀-C₁₃ alkanes), diisopropyleneglycol monomethyl ether, diethyleneglycol diethyl ether, 2-propanol, 2-butanol, t-butanol, 1-hexanol, 2-(2-butoxyethoxy)ethanol, and terpineol. In some embodiments, polyketone solvents can be used in a like manner.

In some embodiments, the organic matrix can contain one or more amines and one or more organic acids. In some embodiments, the one or more amines and one or more organic acids can be present in an organic matrix that also includes one or more hydrocarbons and one or more alcohols. As discussed above, it is believed that amines and organic acids can actively sequester surfactants that have been passively solubilized by hydrocarbon and alcohol solvents, thereby making the surfactants unavailable for re-association with the metal nanoparticles. Thus, an organic solvent that contains a combination of one or more hydrocarbons, one or more alcohols, one or more amines, and one or more organic acids can provide synergistic benefits for promoting the consolidation of metal nanoparticles. Illustrative but non-limiting examples of amine solvents that can be present include, for example, tallowamine (CAS 61790-33-8), alkyl (C₈-C₁₈) unsaturated amines (CAS 68037-94-5), di(hydrogenated tallow)amine (CAS 61789-79-5), dialkyl (C₈-C₂₀) amines (CAS 68526-63-6), alkyl (C₁₀-C₁₆)dimethyl amine (CAS 67700-98-5), alkyl (C₁₄-C₁₈) dimethyl amine (CAS 68037-93-4), dihydrogenated tallowmethyl amine (CAS 61788-63-4), and trialkyl (C₆-C₁₂) amines (CAS 68038-01-7). Illustrative but non-limiting examples of organic acid solvents that can be present in the nanoparticle paste compositions include, for example, octanoic acid, nonanoic acid, decanoic acid, caprylic acid, pelargonic acid, undecylic acid, lauric acid, tridecylic acid, myristic acid, pentadecanoic acid, palmitic acid, margaric acid, stearic acid, nonadecylic acid, α-linolenic acid, stearidonic acid, oleic acid, and linoleic acid.

In some embodiments, the organic matrix can include more than one hydrocarbon, more than one alcohol, optionally more than one glyme (glycol ether), more than one amine, and more than one organic acid. For example, in some embodiments, each class of organic solvent can have two or more members, or three or more members, or four or more members, or five or more members, or six or more members, or seven or more members, or eight or more members, or nine or more members, or ten or more members. Moreover, the number of members in each class of organic solvent can be the same or different. Particular benefits of using multiple members of each class of organic solvent are described hereinafter. Higher boiling organic solvents may provide safety advantages.

One particular advantage of using multiple members within each class of organic solvent can include the ability to provide a wide spread of boiling points in the metal nanoparticle paste compositions. By providing a wide spread of boiling points, the organic solvents can be removed gradually as the temperature rises while affecting metal nanoparticle consolidation, thereby limiting volume contraction and disfavoring cracking. By gradually removing the organic solvent in this manner, less temperature control may be needed to affect slow solvent removal than if a single solvent with a narrow boiling point range was used. In some embodiments, the members within each class of organic solvent can have a window of boiling points ranging between about 50° C. and about 200° C., or between about 50° C. and about 250° C., or between about 100° C. and about 200° C., or between about 100° C. and about 250° C., or between about 150° C. and about 300° C., or between about 150° C. and about 350° C., or between about 150° C. and about 365° C. In more particular embodiments, the various members of each class of organic solvent can each have boiling points that are separated from one another by at least about 20° C., specifically about 20° C. to about 50° C. More specifically, in some embodiments, each hydrocarbon can have a boiling point that differs by about 20° C. to about 50° C. from other hydrocarbons in the organic matrix, each alcohol can have a boiling point that differs by about 20° C. to about 50° C. from other alcohols in the organic matrix, each amine can have a boiling point that differs by about 20° C. to about 50° C. from other amines in the organic matrix, and each organic acid can have a boiling point that differs by about 20° C. to about 50° C. from other organic acids in the organic matrix. The more members of each class of organic solvent that are present, the smaller the differences become between the boiling points. By having smaller differences between the boiling points, solvent removal can be made more continual, thereby limiting the degree of volume contraction that occurs at each stage. A reduced degree of cracking can occur when four to five or more members of each class of organic solvent are present (e.g., four or more hydrocarbons, four or more alcohols, four or more amines, and four or more organic acids; or five or more hydrocarbons, five or more alcohols, five or more amines, and five or more organic acids), each having boiling points that are separated from one another within the above range.

In various embodiments, the metal nanoparticles used in the metal nanoparticle paste compositions can be about 20 nm or less in size. In other various embodiments, metal nanoparticles may be up to about 75 nm in size or even up to about 200 nm in size in at least one dimension. As discussed above, metal nanoparticles in a size range below about 20 nm may have fusion temperatures that are significantly lower than the melting point of the corresponding bulk metal and readily undergo consolidation with one another as a result. In some embodiments, metal nanoparticles that are about 20 nm or less in size can have a fusion temperature of about 220° C. or below (e.g., a fusion temperature in the range of about 140° C. to about 220° C.) or about 200° C. or below, which can provide advantages that are noted above. In some embodiments, at least a portion of the metal nanoparticles can be about 10 nm or less in size, or about 5 nm or less in size. In more specific embodiments, at least a portion of the metal nanoparticles can range from about 1 nm in size to about 20 nm in size, or from about 1 nm in size and about 10 nm in size, or from about 1 nm in size to about 5 nm in size, or from about 3 nm in size to about 7 nm in size, or from about 5 nm in size to about 20 nm in size. In some embodiments, substantially all of the metal nanoparticles can reside within these size ranges. In some embodiments, larger metal nanoparticles can be combined in the metal nanoparticle paste compositions with metal nanoparticles that are about 20 nm in size or less. For example, in some embodiments, metal nanoparticles ranging from about 1 nm to about 10 nm in size can be combined with metal nanoparticles that range from about 25 nm to about 50 nm in size, or with metal nanoparticles that range from about 25 nm to about 100 nm in size, or with metal nanoparticles that range from about 25 nm to about 150 nm in size, or with metal nanoparticles that range from about 25 nm to about 200 nm in size. As further discussed below, micron-scale metal particles, other micron-scale particles, and/or nanoscale particles can also be included in the metal nanoparticle paste compositions in some embodiments. Although larger metal nanoparticles and micron-scale metal particles may not be liquefiable at the low temperatures of their smaller counterparts, they can still become consolidated upon contacting the smaller metal nanoparticles that have been liquefied at or above their fusion temperature, as generally discussed above.

In addition to metal nanoparticles and organic solvents, other additives can also be present in the metal nanoparticle paste compositions. Such additional additives can include, for example, rheology control aids, thickening agents, micron-scale conductive additives, nanoscale conductive additives, and any combination thereof. Chemical additives can also be present. As discussed hereinafter, the inclusion of micron-scale conductive additives, such as micron-scale metal particles, can be particularly advantageous. Nanoscale or micron-scale diamond or other thermally conductive additives may be desirable to include in some instances for promoting more efficient heat transfer and tailoring the CTE. Suitable CTE modifiers, any of which may be in particle or fiber form if not otherwise specified, may include, but are not limited to, carbon fibers, W particles, Mo particles, diamond particles, boron nitride, aluminum nitride, silicon nitride, copper oxide nanoparticles (e.g., about 2 nm to about 200 nm in size containing Cu₂O and/or CuO), carbon nanotubes, graphene, graphite, and the like. Any of the foregoing CTE modifiers may be micron-sized in at least one dimension.

In some embodiments, the paste compositions can contain about 0.01% to about 15% micron-scale metal particles by weight, or about 1% to about 10% micron-scale metal particles by weight, or about 1% to about 5% micron-scale metal particles by weight, or about 0.1% to about 35% micron-scale metal particles by weight, or about 10% to about 60% micron-scale metal particles by weight, or about 25% to about 55% micron-scale metal particles by weight. Inclusion of micron-scale metal particles in the metal nanoparticle paste compositions can desirably reduce the incidence of cracking that occurs during consolidation of the metal nanoparticles when forming bulk metal. Without being bound by any theory or mechanism, it is believed that the micron-scale metal particles can become consolidated with one another as the metal nanoparticles are liquefied and form a transient liquid coating upon the surface of the micron-scale metal particles. In some embodiments, the micron-scale metal particles can range from about 500 nm to about 100 microns in size in at least one dimension, or from about 500 nm to about 10 microns in size in at least one dimension, or from about 100 nm to about 5 microns in size in at least one dimension, or from about 100 nm to about 10 microns in size in at least one dimension, or from about 100 nm to about 1 micron in size in at least one dimension, or from about 1 micron to about 10 microns in size in at least one dimension, or from about 5 microns to about 10 microns in size in at least one dimension, or from about 1 micron to about 100 microns in size in at least one dimension, or from about 1 micron to about 25 microns in at least one dimension, or from about 1 micron to about 5 microns in at least one dimension, or from about 5 micron to about 15 microns in size in at least one dimension. The micron-scale metal particles can contain the same metal as the metal nanoparticles or contain a different metal. Thus, metal alloys can be fabricated by including micron-scale metal particles in the paste compositions with a metal differing from that of the metal nanoparticles. That is, the metal composites may comprise a metal alloy in some instances. Metal alloys may also be formed by combining different types of metal nanoparticles with one another. Suitable micron-scale metal particles can include, for example, Cu, Ni, Al, Fe, Co, Mo, W, Ag, Zn, Sn, Au, Pd, Pt, Ru, Mn, Cr, Ti, V, Mg or Ca particles. Non-metal particles such as, for example, Si and B micron-scale particles can be used in a like manner. In some embodiments, the micron-scale metal particles can be in the form of metal flakes, such as high aspect ratio copper flakes, for example. Thus, in some embodiments, the metal nanoparticle paste compositions described herein can contain a mixture of copper nanoparticles and high aspect ratio copper flakes or another type of micron-scale copper particles. Specifically, in some embodiments, the metal nanoparticle paste compositions can contain about 30% to about 90% copper nanoparticles by weight and about 0.01% to about 15% or 1% to 35% high aspect ratio copper flakes by weight. A CTE modifier may further be present in the metal nanoparticle paste compositions.

Other micron-scale metal particles that can be used equivalently to high aspect ratio metal flakes include, for example, metal nanowires and other high aspect ratio particles, which can be up to about 300 microns in length. The ratio of metal nanoparticles to metal nanowires may range between about 10:1 to about 40:1, according to various embodiments. Suitable nanowires may have a length of about 5 microns to about 50 microns, and a diameter of about 100 nm to about 200 nm or about 100 nm to about 250 nm, for example.

Additional substances that can also optionally be present in the metal nanoparticle paste compositions include, for example, flame retardants, UV protective agents, antioxidants, carbon black, graphite, fiber materials (e.g., chopped carbon fiber materials), diamond, and the like.

In some more specific embodiments, suitable nanoparticle paste compositions may comprise diamond particles or nanodiamond particles. Diamond particles may be sized as large as possible to limit grain boundaries that need to be crossed by phonons during heat transfer while remaining sufficiently small such that dispensability of the metal nanoparticle paste composition is not compromised.

In still more specific embodiments, diamond particles suitable for use in the metal nanoparticle paste compositions may have a size ranging from about 1 micron to about 1000 microns, or from about 0.5 micron to about 500 microns, or from about 1 micron to about 10 microns, or from about 2 micron to about 50 microns or from 50 microns to about 150 microns, which can provide for good particle dispersion and acceptable paste dispensability. Diamond particles having a size ranging from about 200 microns to about 250 microns or about 1 micron to about 10 microns can represent a good compromise between providing effective dispersion and a minimized grain boundary for discouraging phonon scattering. Other suitable size ranges for the diamond particles can range from about 25 microns to about 150 microns, or about 50 microns to about 250 microns, or from about 100 microns to about 250 microns, or from about 100 microns to about 200 microns, or from about 150 microns to about 250 microns, or from about 1 micron to about 100 microns, or from about 10 microns to about 50 microns, or from about 5 microns to about 25 microns.

In illustrative embodiments, the metal composites can include about 10% to about 75% diamond particles by volume after metal nanoparticle consolidation has taken place to form a monolithic metal body. Other conductive particles or CTE modifiers may be present in the same compositional range. In some embodiments, one or more CTE modifiers may be present at 35% or about 60% by weight of the metal composite in the disclosure herein.

Admixture of copper nanoparticles and diamond particles may be desirable for several reasons. Copper is low in cost compared to most other metals, is impedance matched relatively well with diamond, and bears high thermal conductivity on its own. In some embodiments, impedance matching can be further improved by including a carbide-forming additive to form a thin layer (single atom up to about 10 nm thick layer or single atom up to about 50 nm thick layer) of metal carbide upon the diamond particles. Suitable carbide-forming metals may include, for example, Ti, Zr, Hf, Cr, Mo, W, V, Mn, Fe, and any combination thereof. As such, the combination of copper nanoparticles and diamond particles can provide very effective heat transfer in the various embodiments of the present disclosure. For establishing electronic communication between various board layers, copper also affords high electrical conductivity as well. Depending on the particular composition utilized, such as due to the amount of electrically non-conductive additives, the electrical conductivity may be about 30-50% IACS, or about 35-60% IACS, or about 50-75% IACS, or about 55-90% IACS, or about 60-98% IACS (International Annealed Copper Standard).

Nanoparticle paste compositions suitable for use according to the present disclosure can be formulated using any of the metal nanoparticle paste compositions described hereinabove. In addition, according to some embodiments, multiple metals may be present in the metal nanoparticle paste compositions. In some or other embodiments, suitable metal nanoparticle paste compositions can include a mixture of metal nanoparticles, other nano-sized particles (i.e., particles having a dimension of about 200 nm or less), and/or micron-scale particles, including micron-scale metal particles. The metal nanoparticle paste compositions may comprise copper nanoparticles, according to more specific embodiments. In some embodiments, copper nanoparticles may be the majority component (>50%) by weight of the metal nanoparticle paste compositions.

Various heat spreaders and printed circuit boards utilizing heat spreaders may be formed, at least in part, from copper nanoparticles and copper nanoparticle paste compositions. In particular, the copper nanoparticles or copper nanoparticle paste compositions may be utilized for producing at least a surface portion of the heat spreaders. For example, copper nanoparticle paste compositions comprising a CTE modifier may be consolidated to form at least a partial coating upon a thermally conductive body, wherein the coating may fulfill various functions described herein, or the copper nanoparticle paste compositions may be consolidated to form the thermally conductive body itself. It is to be appreciated that alternative metal nanoparticles may be utilized to form a conductive body or a coating upon a conductive body defining a heat spreader, as may be needed to facilitate CTE matching to some ceramic materials within a heat-producing component. Thus, it is to be understood that any embodiment utilizing copper or copper nanoparticles in the disclosure following hereinafter may utilize alternative metals or metal nanoparticles depending on application-specific needs (optionally in combination with copper), unless otherwise specified to the contrary.

Similarly, copper nanoparticle paste compositions may be applied as a bonding layer between a heat-producing component and a heat spreader containing a copper composite on at least a surface thereof. Following consolidation of the metal nanoparticles, the resulting bulk metal may provide a CTE-matched bonding interface between the heat-producing component and a surface of the heat spreader (also formed from consolidated metal nanoparticles). The bonding layer may form a complete or partial coating upon at least one face of the heat spreader in some embodiments. The bonding layer may be multi-layered, with the CTE of each layer differing, in some embodiments. The bonding layer may be metallurgically bonded to the heat spreader, but is not necessarily bonded to the heat-producing component. In any event, the bonding layer may have a CTE that is intermediate between the CTE of the heat-producing component and the heat spreader. A similar bonding layer may be interposed between the heat spreader and the heat sink or similar heat-receiving structure, wherein the heat spreader may be optionally metallurgically bonded to the heat sink or similar heat-receiving structure, and the bonding layer may have a CTE that is intermediate between the CTE of the heat spreader and the heat sink or similar heat-receiving structure, such as a heat pipe.

Heat spreaders of the present disclosure may comprise a thermally conductive body configured to contact a heat source and a heat sink, in which at least a portion of the thermally conductive body is CTE matched to a heat-producing component. In particular, at least a portion of the thermally conductive body, a complete or partial coating upon the thermally conductive body, or an interface material (bonding layer) between the thermally conductive body and a heat-producing component may comprise a copper composite that includes a CTE modifier, as described further herein. The thermally conductive body may be a monolithic block, which may comprise a metal, metal alloy, or metal composite. The thermally conductive body may define a heat spreader that is tapered. Tapering of a heat spreader may disperse the heat at a cold end thereof and reduce the thermal load per unit area at this location. Various heat spreader configurations are specified hereinafter in reference to the drawings.

In various embodiments, the copper composite may be formed through consolidation of copper nanoparticles with micron-size copper particles and a CTE modifier, or consolidation of copper nanoparticles with a CTE modifier without including micron-scale copper particles. The copper nanoparticles, the micron-size copper particles (if present), and the CTE modifier may define a copper nanoparticle paste composition, as specified in more detail above. The copper nanoparticle paste compositions may be utilized to form a thermally conductive body of a heat spreader, a coating upon a thermally conductive body of a heat spreader, or as a bonding interface material between a heat spreader and a heat-producing component. Suitable copper nanoparticle paste compositions may comprise about 30 wt. % to about 60 wt. % copper nanoparticles, about 5 wt. % to about 50 wt. % micron-size copper particles, and an effective amount of the CTE modifier to target a specified CTE. The CTE modifier may be present in an amount ranging from about 1% to about 35% by weight, or about 4% to about 8% by weight, or about 5% to about 15% by weight, or about 10% to about 20% by weight, or even about 35% or about 60% by weight. One or more CTE modifiers may be present, including two, three, four, or five or more different CTE modifiers. The micron-size copper particles may be omitted in some embodiments.

Suitable CTE modifiers may include, but are not limited to, graphite/pitch-based carbon fibers (e.g., having 10 micron diameters), W particles, Mo particles, diamond particles, boron nitride particles or fibers, aluminum nitride particles or fibers, silicon nitride particles or fibers, carbon nanotubes, graphene, graphite powder, the like, and any combination thereof. Unless otherwise specified, the CTE modifiers may be in one or more forms such as powders, particles, fibers, flakes, or the like. An amount of CTE modifier may be selected to provide a desired extent of CTE matching. Carbon-based additives, for example, can achieve about 2-3 ppm thermal expansion when added at about 16% by volume, or about 7 ppm thermal expansion when added at about 9% by volume, or about 6 ppm when added at about 11% by volume. Adding diamond at about 45% by volume can achieve about 5-6 ppm thermal expansion depending on density (82%). At about 37% loading by volume and 93% density, the thermal expansion provided by diamond may be about 6 ppm. At a diamond loading of more than about 50% by volume, the thermal expansion drops below about 5 ppm.

The CTE modifier may also significantly increase the thermal conductivity in some cases. Carbon nanotubes, for example, may increase the thermal conductivity of the copper up to about 600 W/m·K from a value in the low 400 s W/m·K for bulk copper alone. The degree of thermal conductivity modification achievable with carbon nanotubes may depend upon the length of the carbon nanotubes, with longer carbon nanotubes exceeding a thermal conductivity value of about 600 W/m·K.

Consolidated copper nanoparticles by themselves exhibit a thermal expansion of about 7-12 ppm depending on the process conditions and density. With increasing density, the thermal expansion approaches that of bulk copper (17 ppm). At about 91% density, the thermal expansion is about 7-8 ppm, and at about 93% density, the thermal expansion increases to about 10-11 ppm. At about 98% density, the thermal expansion reaches about 12 ppm. Even at such high density values, the thermal expansion is still below the value for bulk copper, which is presumed to arise from the nanoporosity present following copper nanoparticle consolidation.

Addition of micron-scale metal particles to metal nanoparticles (e.g., copper nanoparticles) can increase the thermal expansion to reach 17 ppm and beyond depending on the specific metal. Addition of Al particles, for example, having a bulk CTE of about 23-24 ppm, can increase the CTE of the resulting composite to a value exceeding that of bulk copper. Addition of about 55% micron-scale copper powder results in a thermal expansion of about 14 ppm at a density of 96%.

The thermally conductive body of the heat spreaders disclosed herein may comprise a monolithic block of metal, a metal alloy, or a metal composite. When the thermally conductive body comprises a metal composite, additional components within the metal composite, such as CTE modifiers, diamond particles or other types of particles having high thermal conductivity, may be distributed throughout the thermally conductive body such that no portion of the thermally conductive body lacks the additional component. That is, the thermally conductive body does not contain a compositional discontinuity in which an additional component, such as a CTE modifier, is not present within a portion of the thermally conductive body. Accordingly, the additional component, such as a CTE modifier, may be distributed uniformly in concentration within the thermally conductive body or change in concentration in a continuous gradient or stepped gradient fashion. The thermally conductive body may increase in size from a “hot” end contacting a heat-producing component and a “cold” end configured to dissipate heat to a heat sink or other thermal reservoir, such as ambient atmosphere, a marine environment, or a radiator to outer space. The loading of additional components may increase or decrease in concentration from the hot end to the cold end in the heat spreader configurations disclosed herein.

In some embodiments, the heat spreaders may comprise a multi-layered interface that promotes a gradual CTE change in a gradient or stepwise manner. The amount of CTE modifier and/or the composition of the CTE modifier in each layer of the multi-layered interface may be adjusted to afford a desired degree of CTE difference between each layer. Stepwise or gradient changing of the CTE may provide less thermal stress between the heat-producing component and the heat spreader than if there was a more abrupt CTE change at the junction between the two. Any number of layers may be present in the multi-layered structure, such as 2, 3, 4, 5, 6, 7, 8, 9, or 10 layers. Each layer may range from about 1 micron to about 25 microns in thickness, or about 5 microns to about 10 microns in thickness. The CTE may change between each layer in an amount ranging from about 1 ppm to about 2.5 ppm, or about 0.8 ppm to about 1.5 ppm, or about 1 ppm to about 2 ppm, or about 1.5 ppm to about 2.2 ppm. For example, the CTE may be stepped from 4 ppm at the heat-producing component (e.g., containing SiC) to 17 ppm at the heat spreader by 5 layers having successive CTEs of about 6.0, 8.2, 10.5, 12.8, and 15.0 ppm or 10 layers having successive CTEs of about 5, 6.1, 7.3, 8.7, 10.1, 11.5, 12, 13.7, 14.9, and 16 ppm. The multi-layered interface may be present as a bonding layer upon the surface of the heat spreader in some cases.

Heat spreaders disclosed herein may be in any specified shape. Without limitation, the heat spreaders may be round, prismatic, ovular, triangular, flat, flattened, or the like. The heat spreaders may be tapered or non-tapered. When tapered, the heat spreaders may increase in size from a hot end to a cold end. Tapering may be continuous or discontinuous.

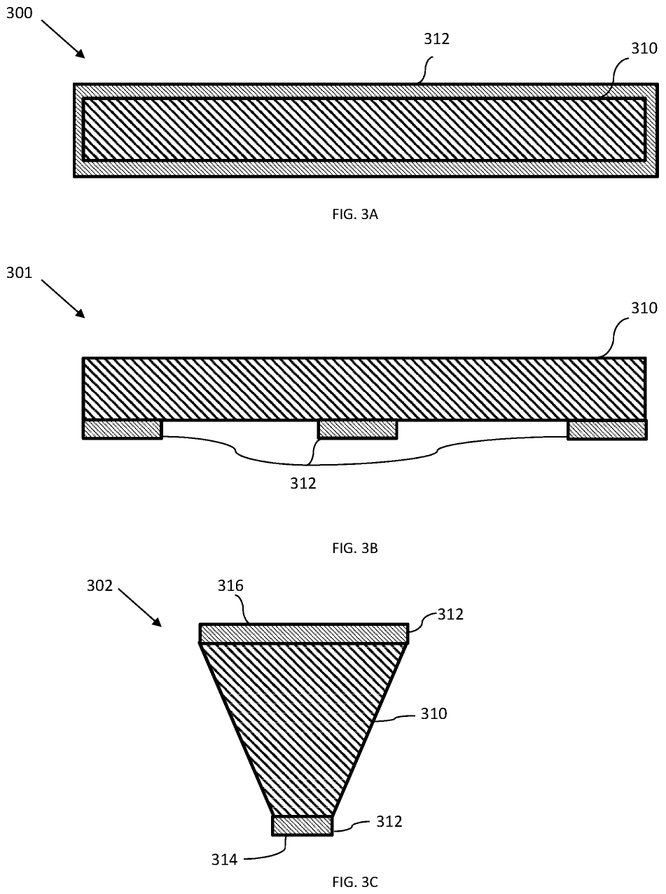

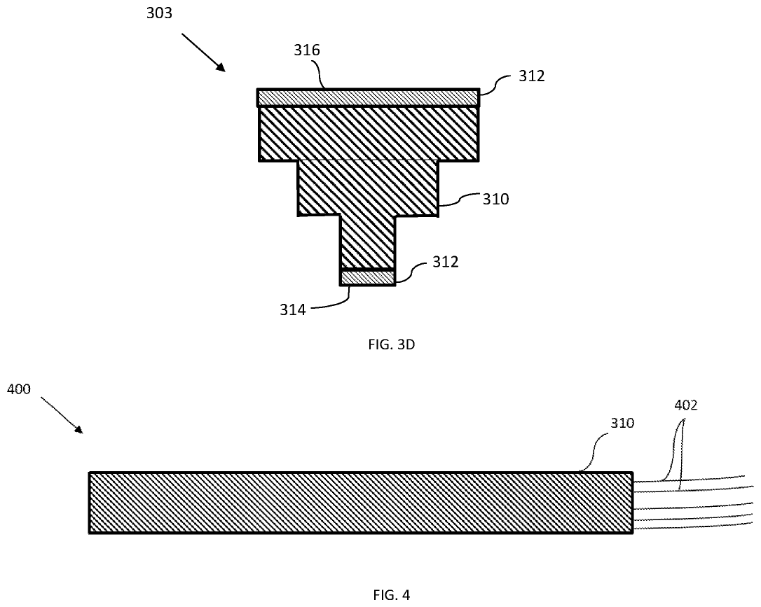

FIGS. 3A-3D show cross-sectional diagrams of various configurations of heat spreaders of the present disclosure. In FIG. 3A, heat spreader 300 includes thermally conductive body 310 and coating 312 disposed continuously upon thermally conductive body 310. At least a portion of coating 312 may comprise a metal composite suitable for CTE matching according to the disclosure herein. Alternately, the thermally conductive body may comprise a metal composite suitable for CTE matching according to the disclosure herein, but without a separate metal composite coating being present. When present, coating 312 need not necessarily be a continuous coating as shown in FIG. 3A. FIG. 3B shows a diagram of heat spreader 301 in which coating 312 is discontinuous upon thermally conductive body 310. The discontinuous coating shown in FIG. 3B may be utilized to form a thermal connection and/or bond to a heat-producing component (not shown). When disposed as a discontinuous coating, the discontinuous coating may intercede between at least a portion of a space between a heat-producing component and thermally conductive body 302. A metal nanoparticle paste composition may be placed in the space between the heat-producing component and thermally conductive body 302 to afford a bonding layer therebetween.

Heat spreaders of the present disclosure may be tapered to afford more effective heat spreading. In FIG. 3C, heat spreader 302 includes thermally conductive body 310 that is continuously tapered with coating 312 located upon at least a portion of thermally conductive body 310, and in FIG. 3D, heat spreader 303 includes thermally conductive body 310 that is discontinuously tapered with coating 312 located upon at least a portion of thermally conductive body 310. Again, coating 312 may be formed by consolidating a metal nanoparticle paste composition comprising a CTE modifier between thermally conductive body 310 and a heat-producing component, thus establishing a bonding layer therebetween. In both heat spreaders 302 and 303, surface 314 may contact a heat source (heat-producing component) and surface 316 may contact or be in thermal communication with a heat sink or similar heat-receiving structure, such as a heat pipe (heat source and heat sinks not shown in FIGS. 3C and 3D). For example, surface 314 may contact an electronic component producing excess heat.

When forming a thermally conductive body of a heat spreader using a metal nanoparticle paste composition comprising a CTE modifier, the metal nanoparticle paste composition may be loaded into a suitable mold or die, and the copper nanoparticles may then undergo consolidation to form a monolithic metal block comprising the CTE modifier. To form a coating upon a thermally conductive body or to form a bonding layer between a thermally conductive metal body and a heat-producing component, a metal nanoparticle paste composition may be applied to the thermally conductive metal body or be sandwiched between the thermally conductive metal body and a heat-producing component, at which point the metal nanoparticles in the metal nanoparticle paste composition may undergo consolidation to form the metal composite, such as a copper composite containing a CTE modifier. Suitable conditions for processing the metal nanoparticle paste composition may include, for example, injection molding, hot pressing, or similar disposition and consolidation techniques. Localized heating of the metal nanoparticles may be conducted during the disposition and consolidation process. Localized, rapid heating to form a metal composite may be performed with a laser or Xe lamp, for example, in non-limiting embodiments. Desirably, metal nanoparticle fusion to form the metal composite may be affected in the absence of an inert atmosphere or a reducing atmosphere, particularly when rapid heating is performed.

A plurality of conductive fibers may extend from one end of the heat spreader in some configurations. FIG. 4 shows a diagram of illustrative heat spreader 400 in which a plurality of conductive fibers 402 extend from one end of thermally conductive body 310. When so configured, conductive fibers 402 may provide a high surface area for dissipation of conducted heat to a heat sink or similar thermal reservoir. In the configuration shown in FIG. 4, thermally conductive body 310 is formed from a metal composite containing a CTE modifier, and no separate coating (e.g., coating 312) is present thereon. The metal composite is produced by consolidation of metal nanoparticles, as described in more detail above. As such, conductive fibers 402 may be incorporated in thermally conductive body 310 during its formation, specifically by inserting conductive fibers 402 into a metal nanoparticle paste composition formed in the shape of conductive body 310 and then consolidating the metal nanoparticles. It is to be appreciated that conductive fibers 402 may alternately become bonded to heat spreader 400 through consolidation of metal nanoparticles within a separate coating, if present. Other than conductive fibers 402 extending from thermally conductive body 310 (or a coating thereon), heat spreader 400 is similar to heat spreaders 300-303 (FIGS. 3A-3D) and may be better understood by reference thereto. Common reference characters are used to denote elements having similar structure and function. Accordingly, any of heat spreaders 300-303 may similarly incorporate conductive fibers 402 in a manner like that described in reference to heat spreader 400.

To introduce conductive fibers 402 to heat spreader 400, an unconsolidated metal nanoparticle paste composition may first be applied to thermally conductive body 310 (or used to form thermally conductive body 310), and conductive fibers 402 may then be positioned in the unconsolidated copper nanoparticle paste composition. Following consolidation of the copper nanoparticles, conductive fibers 402 may become firmly affixed to heat spreader 400 in a matrix of bulk copper and dispersed CTE modifier formed from the copper nanoparticle paste composition.

Suitable conductive fibers may include, but are not limited to, graphite fiber bundles, which may exhibit thermal conductivity values that are double or more that of bulk copper (e.g., 800-1100 W/m·K or 550-1200 W/m·K). Other suitable conductive fibers may include, but are not limited to, metal fibers (e.g., Al or Cu fibers), diamond fibers, carbon nanotubes or carbon nanotube fibers, or any combination thereof. Suitable fiber lengths may be about 2-8 inches, depending on fiber flexibility. Suitable fiber diameters may be about 5-50 microns, or about 5-10 microns, or about 5-20 microns, or about 30-50 microns. Fibers may also be in the form of porous foams extending from the thermally conductive body (or a coating thereon), in which case a cooling fluid, such as air or a liquid, may pass through the pores of the foam and/or over or through the fibers to carry away excess heat.

The heat spreaders disclosed herein may be utilized to dissipate heat from a heat-producing component associated with a printed circuit board. The heat-producing component may comprise a ceramic such as, for example, Si (CTE=2.6 ppm), SiC (CTE=4.2 ppm), GaN (CTE=5.6 ppm), or AlN (CTE=4.5 ppm). In non-limiting examples, the CTE of the heat spreader may match the CTE of the heat-producing component within a tolerance about ±50%, or within about ±25%, or within about ±20%, or within about ±15%, or within about ±10%, or within about ±5%, or within about ±4%, or within about ±3%, or within about ±2%, or within about ±1%. The thermally conductive body of the heat spreader or a coating thereon may exhibit a CTE value at room temperature ranging from about 2 ppm to about 6 ppm, or about 3 ppm to about 7 ppm, or about 5 ppm to about 10 ppm, or about 10 ppm to about 15 ppm, or about 15 ppm to about 25 ppm.

Accordingly, in some embodiments, the present disclosure provides heat dissipation systems employing a heat spreader which may be CTE matched to a heat-producing component and a heat sink or similar heat-receiving structure. The CTE matching may be with ±20% in a non-limiting example. The heat dissipation systems may comprise: a heat spreader having a thermally conductive body, in which at least a portion of the thermally conductive body or a coating thereon comprises a copper composite that comprises a coefficient of thermal expansion (CTE) modifier, such that the thermally conductive body has a CTE of about 3 ppm to about 7 ppm; a heat-producing component in contact with a first surface of the thermally conductive body, the heat-producing component having a CTE of about 3 ppm to about 7 ppm; and a heat sink or a heat pipe in contact with a second surface of the thermally conductive body; wherein the heat sink or the heat pipe is also formed from the copper composite comprising the coefficient of thermal expansion modifier and has a CTE of about 3 to about 7 ppm. Optionally, the thermally conductive body of the heat spreader may be metallurgically bonded to the heat sink or the heat pipe while accomplishing the foregoing CTE matching. Heat dissipation systems having the foregoing features may be utilized in conjunction with printed circuit boards and other electronic components producing excess heat, in non-limiting examples.

Printed circuit boards of the present disclosure may comprise: a heat-producing component located upon or recessed within an electrically insulating substrate, and at least one heat spreader in thermal communication with the heat-producing component, in which the at least one heat spreader is CTE-matched to at least the heat-producing component. The at least one heat spreader may be in thermal communication with the heat-producing component through direct or indirect physical contact and bonding with the heat-producing component. The electrically insulating substrate may also be thermally insulating, such as FR4, or thermally conductive, such as AlN or SiN. In various examples, the at least one heat spreader is a heat spreader of the present disclosure, at least a portion of which comprises a metal composite formed from metal nanoparticles and a CTE modifier (e.g., a copper composite comprising a CTE modifier). The at least one heat spreader may be bonded to the heat-producing component directly via a thermally conductive body, indirectly via a coating upon the thermally conductive body, or indirectly via a bonding layer comprising a copper composite that is CTE-matched to the heat-producing component and at least a portion of the heat spreader.

It is to be appreciated that printed circuit boards also refer equivalently herein to alternative structures having similar heat dissipation issues, such as SIPs and packaged electronics.

The heat-producing component may be located upon a top surface of the electrically insulating substrate, or buried within a recess within the electrically insulating substrate. The at least one heat spreader may be bonded to a top surface of the heat-producing component or a bottom surface of the heat-producing component, one or more heat spreaders may be bonded to a side surface of the heat-producing component, or any combination thereof. Particular configurations are provided hereinafter.

FIG. 5 shows a diagram in which a heat spreader is bonded to a top surface of a heat-producing component. As shown, PCB 600 includes electrically insulating substrate 602 and heat-producing component 604 thereupon. Heat spreader 606 is bonded to a top surface of heat-producing component 604. Heat spreader 606 may be incorporated into and/or be part of a an integrated circuit housing in some cases. Although not depicted in FIG. 5, heat-producing component 604 may be recessed into electrically insulating substrate 602, and heat spreader 606 may rest upon the surface of electrically insulating substrate 602.

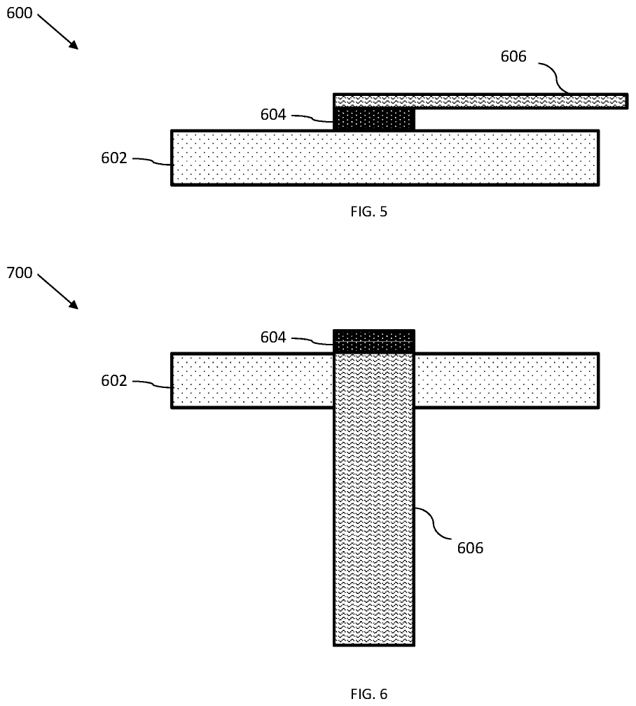

FIG. 6 shows a diagram in which a heat spreader is bonded to a bottom surface of a heat-producing component. In this configuration, heat spreader 606 extends through a via defined in electrically insulating substrate 602 of PCB 700 and contacts the backside of heat-producing component 604. The via may be suitably sized for heat spreader 606 to extend therethrough. Heat spreader 606 may increase in lateral size (increasing taper) after passing through the via. Although not depicted in FIG. 6, heat-producing component 604 may be recessed into electrically insulating substrate 602.

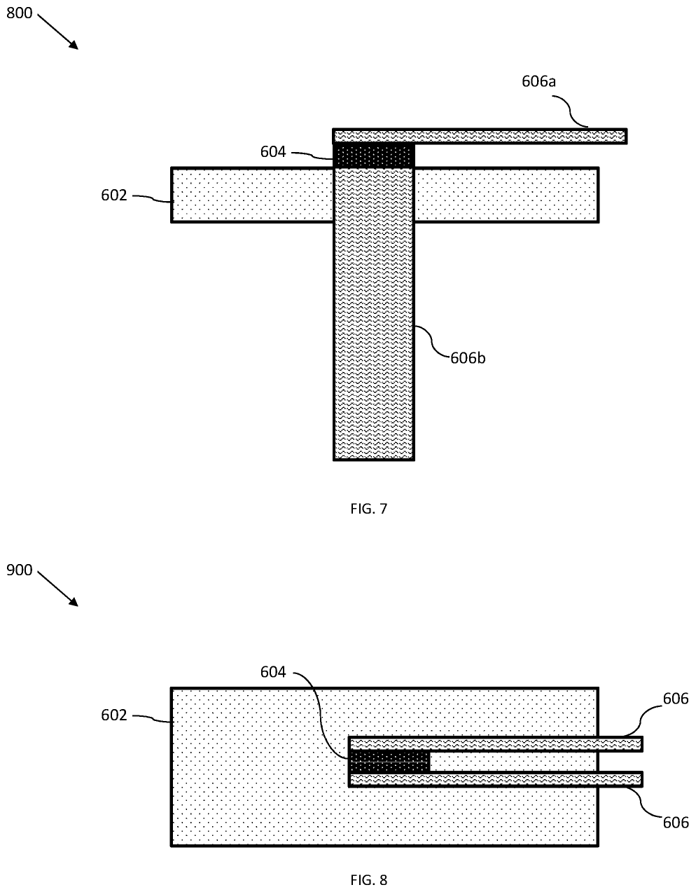

Heat spreaders may also be bonded to the top and bottom surfaces of the heat-producing component, as shown in FIG. 7. In PCB 800, heat spreader 606a is bonded to the top surface of heat-producing component 604, and heat spreader 606b extends through electrically insulating substrate 602 and is bonded to a bottom surface of heat-producing component 604. Although not depicted in FIG. 7, heat-producing component 604 may be recessed into electrically insulating substrate 602.

FIG. 8 shows a diagram in which multiple heat spreaders are bonded to a side surface of a heat-producing component. In FIG. 8, a top view of PCB 900 is shown, looking down upon heat-producing component 604 and heat spreaders 606 upon the top surface of electrically insulating substrate 602. Heat spreaders 606 are bonded to the sides of heat-producing component 604. Although two heat spreaders 606 are shown with side bonding in PCB 900, it is appreciated that one or more than two heat spreaders 606 may be bound similarly. Side binding of heat spreaders 606 may facilitate stacking into multiple PCB layers. It is to be appreciated that top and bottom heat spreaders (see FIGS. 5-7), although not shown, may also be present.

Accordingly, PCBs incorporating a heat spreader of the present disclosure may be single-layer or multi-layer, according to various embodiments. Multi-layer PCBs can contain individual layers that are laminated together to define vias and other board features.

In various embodiments, a bonding layer in between the heat spreader and the heat-producing component may comprise copper and be formed from copper nanoparticles, more particularly a copper nanoparticle paste composition containing other additives suitable to modify the CTE to match that of the heat-producing component. The CTE modifier may comprise carbon fibers, diamond particles, boron nitride, aluminum nitride, silicon nitride, carbon nanotubes, graphene, graphite, copper oxide nanoparticles, or the like. Other additives may be present in the copper nanoparticle paste composition to facilitate dispensation and handling. The bonding layer may comprise a second copper composite and may be further CTE-matched to the copper composite of the heat spreader as well.

Embodiments disclosed herein include:

A. Heat spreaders. The heat spreaders comprise: a thermally conductive body configured to contact a heat source and a heat sink, in which at least a portion of the thermally conductive body or a coating thereon comprises a copper composite that comprises a coefficient of thermal expansion (CTE) modifier.

B. Printed circuit boards comprising: a heat-producing component located upon or recessed within an electrically insulating substrate; and
at least one heat spreader in thermal communication with the heat-producing component, the at least one heat spreader comprising:
   a thermally conductive body, in which at least a portion of the thermally conductive body or a coating thereon comprises a copper composite that comprises a coefficient of thermal expansion (CTE) modifier.

C. Heat dissipation systems. The heat dissipation systems comprise: a heat spreader having a thermally conductive body, in which at least a portion of the thermally conductive body or a coating thereon comprises a copper composite that comprises a coefficient of thermal expansion (CTE) modifier, such that the thermally conductive body has a CTE of about 3 ppm to about 7 ppm; a heat-producing component in contact with a first surface of the thermally conductive body, the heat-producing component having a CTE of about 3 ppm to about 7 ppm; and a heat sink or a heat pipe in contact with a second surface of the thermally conductive body; wherein the heat sink or the heat pipe is also formed from the copper composite comprising the coefficient of thermal expansion modifier and has a CTE of about 3 to about 7 ppm. Optionally, the thermally conductive body or the coating thereon may have a CTE within about +20% of that of the heat-producing component. Optionally, the thermally conductive body or the coating thereon may have a CTE within about +20 of that of the heat sink or heat pipe. Optionally, the thermally conductive body or the coating thereon may be metallurgically bonded to the heat-producing component and/or the heat sink or the heat pipe via a bonding layer.

Each of embodiments A-C may have one or more of the following additional elements in any combination:

Element 1: wherein the copper composite is formed through consolidation of copper nanoparticles with micron-size copper particles and the CTE modifier.

Element 1A: wherein the copper composite is formed through consolidation of copper nanoparticles with the CTE modifier.

Element 2: wherein the copper composite has a uniform nanoporosity of about 2% to about 30%.

Element 3: wherein the CTE modifier comprises particles or fibers selected from the group consisting of carbon, W, Mo, diamond, boron nitride, aluminum nitride, silicon nitride, carbon nanotubes, graphene, graphite, copper oxide nanoparticles, and any combination thereof.

Element 4: wherein the heat spreader further comprises a plurality of thermally conductive fibers extending from at least a portion of the thermally conductive body or the coating thereon, if present.

Element 5: wherein the thermally conductive body is wholly formed from the copper composite comprising the CTE modifier.

Element 6: wherein the CTE modifier is distributed throughout the thermally conductive body.

Element 7: wherein the thermally conductive body is tapered.

Element 8: wherein the CTE modifier is present in the copper composite in a stepwise or gradient concentration distribution

Element 9: wherein the at least one heat spreader is bonded to the heat-producing component via a bonding layer comprising a copper composite that is CTE-matched to the heat-producing component. Optionally, the CTE of the heat-producing component and the CTE of the thermally conductive body and/or the coating thereon differ by about +20% or less, or about ±10% or less, or +5% or less.

Element 10: wherein the copper composite of the bonding layer has a uniform nanoporosity of about 2% to about 30%.

Element 11: wherein the heat-producing component is located upon or recessed within a surface of the electrically insulating substrate, and: the at least one heat spreader is bonded to a top surface of the heat-producing component, one or more heat spreaders are bonded to a side surface of the heat-producing component, the at least one heat spreader is bonded to a bottom surface of the heat-producing component and the at least one heat spreader extends through the electrically insulating substrate, or any combination thereof.

By way of non-limiting example, exemplary combinations applicable to A-C include, but are not limited to: 1 or 1A, and 2; 1 or 1A, and 3; 1 or 1A, and 4; 1 or 1A, and 5; 1 or 1A, and 6; 1 or 1A, and 7; 1 or 1A, and 8; 2 and 3; 2 and 4; 2 and 5; 2 and 6; 2 and 7; 2 and 8; 3 and 4; 3 and 5; 3 and 6; 3 and 7; 3 and 8; 4 and 5; 4 and 6; 4 and 7; 4 and 8; 5 and 6; 5 and 7; 5 and 8; 6 and 7; 6 and 8; and 7 and 8. With respect to B and C any of the foregoing may be in further combination with 9, 10 or 11. Additional exemplary combinations applicable to B and C include, but are not limited to, 9 and 10; 9 and 11; 10 and 11; and 9-11.

To facilitate a better understanding of the embodiments of the present disclosure, the following examples of preferred or representative embodiments are given. In no way should the following examples be read to limit, or to define, the scope of the invention.

### EXAMPLES

Example 1. To produce a 11.7 mm tall and 0.5″ wide solid cylinder, 2.7 mL of a 5.1 g/ccm dense paste containing 43% v/v of commercial dry graphite powder, 24% v/v of commercial dry copper powder and 33% v/v of copper nanoparticles was loaded into a graphite cell 3″ tall×2″ wide with a 0.5″ bore closed out on both ends with tightly fit graphite rods. The cell was then placed in a hydraulic press. An initial pressure of 250 psi was applied while the cell was heated to 250° C. At 100° C., the pressure was increased to 500 psi, at 200° C. to 1000 psi, and at 250° C. to 1750 psi, which was then maintained throughout the process. The target peak temperature was reached after about 15 minutes and maintained for another 75 minutes. After that, the heat was shut off, the cell was cooled to room temperature, and the part was pushed out. The cylinder weighed 12.2 g and was 92% dense.

Example 2. To produce a 6.8 mm tall and 0.5″ wide solid cylinder, 1.6 mL of a 4.9 g/ccm dense paste containing 33% v/v of commercial dry BN powder, 33% v/v of commercial dry copper powder and 34% v/v of copper nanoparticles was loaded into a graphite cell 3″ tall×2″ wide with a 0.5″ bore closed out on both ends with tightly fit graphite rods. The cell was then placed in a hydraulic press. An initial pressure of 250 psi was applied while the cell was being heated to 250° C. At 100° C., the pressure was increased to 500 psi, at 200° C. to 1000 psi, and at 235° C. to 1750 psi, which was then maintained throughout the process. The target peak temperature was reached after about 10 minutes and maintained for another 45 minutes. After that, the heat was shut off, the cell was cooled to room temperature, and the part was pushed out. The cylinder weighed 6.9 g and was 90% dense.

Example 3. To produce a 15.6 mm tall and 0.5″ wide solid cylinder, 2.9 mL of a 4.3 g/ccm dense paste containing 7% v/v of commercial dry diamond powder, 23% v/v of commercial dry copper powder and 70% v/v of copper nanoparticles was loaded into a graphite cell 3″ tall×2″ wide with a 0.5″ bore closed out on both ends with tightly fit graphite rods. The cell was then placed in a hydraulic press. An initial pressure of 250 psi was applied while the cell was being heated to 250° C. At 100° C., the pressure was increased to 500 psi, at 200° C. to 1400 psi, and at 235° C. to 1850 psi, which was then maintained throughout the process. The target peak temperature was reached after about 15 minutes and maintained for another 85 minutes. After that, the heat was shut off, the cell was cooled to room temperature, and the part was pushed out. The cylinder weighed 11.7 g and was 92% dense.

Additional samples were made in a similar manner to that described above for Examples 1-3. Metal composite compositions and CTE values obtained therefrom at various temperatures are specified in Table 1.

TABLE 1

| | CTE | CTE | | | | |
|---|---|---|---|---|---|---|
| | Modifier | Modifier | Copper | CTE (ppm) | | |
| | #1 | #2 | Nanoparticles | 40° | 100° | 200° |
| Sample | (v/v) | (v/v) | (v/v) | C. | C. | C. |
| 1 | graphite | metal | 33% | 2.82 | 4.57 | 9.08 |
| | (43%) | (24%) | | | | |
| 2 | graphite | metal | 35% | 3.57 | 5.58 | 5.14 |
| | (43%) | (22%) | | | | |
| 3 | diamond | BN | 30% | 5.44 | 4.29 | 3.87 |
| | (66%) | (4%) | | | | |
| 4 | graphite | metal | 41% | 6.06 | 10.89 | 15.82 |
| | (33%) | (26%) | | | | |
| 5 | diamond | — | 40% | 6.09 | 8.47 | 8.95 |
| | (60%) | | | | | |
| 6 | graphite | — | 72% | 6.86 | 9.16 | 12.44 |
| | (28%) | | | | | |
| 7 | — | — | 100% | 7.11 | 8.25 | 12.07 |
| 8 | BN | metal | 34% | 8.18 | 11.36 | 16.57 |
| | (33%) | (33%) | | | | |
| 9 | graphite | metal | 35% | 8.24 | 8.78 | 10.95 |
| | (43%) | (22%) | | | | |
| 10 | diamond | metal | 55% | 8.87 | 13.66 | 15.73 |
| | (24%) | (21%) | | | | |
| 11 | diamond | metal | 41% | 9.06 | 13.29 | 15.88 |
| | (24%) | (35%) | | | | |
| 12 | graphite | metal | 47% | 9.28 | 12.86 | 16.53 |
| | (17%) | (36%) | | | | |
| 13 | diamond | metal | 51% | 9.60 | 12.85 | 14.75 |
| | (29%) | (20%) | | | | |
| 14 | graphite | metal | 33% | 9.94 | 9.44 | 9.84 |
| | (43%) | (24%) | | | | |
| 15 | BN | metal | 41% | 9.95 | 12.89 | 16.27 |
| | (24%) | (35%) | | | | |
| 16 | graphite | metal | 48% | 10.15 | 13.71 | 17.93 |
| | (14%) | (38%) | | | | |
| 17 | graphite | metal | 35% | 10.39 | 14.41 | 18.51 |
| | (14%) | (51%) | | | | |
| 18 | graphite | — | 57% | 11.77 | 16.89 | 21.02 |
| | (43%) | | | | | |
| 19 | — | metal | 76% | 14.87 | 16.20 | 17.26 |
| | | (24%) | | | | |
| 20 | diamond | metal | 70% | 15.26 | 17.28 | 17.79 |
| | (7%) | (23%) | | | | |

Unless otherwise indicated, all numbers expressing quantities of ingredients, properties such as molecular weight, reaction conditions, and so forth used in the present specification and associated claims are to be understood as being modified in all instances by the term “about.” Accordingly, unless indicated to the contrary, the numerical parameters set forth in the following specification and attached claims are approximations that may vary depending upon the desired properties sought to be obtained by the embodiments of the present invention. At the very least, and not as an attempt to limit the application of the doctrine of equivalents to the scope of the claim, each numerical parameter should at least be construed in light of the number of reported significant digits and by applying ordinary rounding techniques.

One or more illustrative embodiments incorporating the features of the present disclosure are presented herein. Not all features of a physical implementation are described or shown in this application for the sake of clarity. It is understood that in the development of a physical embodiment incorporating the present disclosure, numerous implementation-specific decisions must be made to achieve the developer's goals, such as compliance with system-related, business-related, government-related and other constraints, which vary by implementation and from time to time. While a developer's efforts might be time-consuming, such efforts would be, nevertheless, a routine undertaking for those of ordinary skill in the art and having benefit of this disclosure.

Therefore, the present disclosure is well adapted to attain the ends and advantages mentioned as well as those that are inherent therein. The particular embodiments disclosed above are illustrative only, as the present disclosure may be modified and practiced in different but equivalent manners apparent to those skilled in the art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present invention. The disclosure herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some amount. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately α-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the element that it introduces.

What is claimed is:

1. A heat spreader comprising:
a thermally conductive body configured to contact a heat source and a heat sink, in which at least a portion of the thermally conductive body or a coating thereon comprises a copper composite that comprises copper nanoparticles and a coefficient of thermal expansion (CTE) modifier.

2. The heat spreader of claim 1, wherein the copper composite is formed through consolidation of the copper nanoparticles with micron-size copper particles and the CTE modifier.

3. The heat spreader of claim 1, wherein the copper composite has a uniform nanoporosity of about 2% to about 30%.

4. The heat spreader of claim 1, wherein the CTE modifier comprises particles or fibers selected from the group consisting of carbon, W, Mo, diamond, boron nitride, aluminum nitride, silicon nitride, carbon nanotubes, graphene, graphite, copper oxide nanoparticles, and any combination thereof.

5. The heat spreader of claim 1, further comprising: a plurality of thermally conductive fibers extending from at least a portion of the thermally conductive body or the coating thereon, if present.

6. The heat spreader of claim 1, wherein the thermally conductive body is wholly formed from the copper composite comprising the CTE modifier.

7. The heat spreader of claim 6, wherein the CTE modifier is distributed throughout the thermally conductive body.

8. The heat spreader of claim 1, wherein the thermally conductive body is tapered.

9. The heat spreader of claim 1, wherein the CTE modifier is present in the copper composite in a stepwise or gradient concentration distribution.

10. The heat spreader of claim 1, wherein the copper composite has a CTE of about 3 ppm to about 7 ppm.

11. A printed circuit board (PCB) comprising:
a heat-producing component located upon or recessed within an electrically insulating substrate; and
at least one heat spreader in thermal communication with the heat producing component, the at least one heat spreader comprising:
a thermally conductive body, in which at least a portion of the thermally conductive body or a coating thereon comprises a copper composite that comprises copper nanoparticles and a coefficient of thermal expansion (CTE) modifier.

12. The PCB of claim 11, wherein the copper composite is formed through consolidation of the copper nanoparticles with micron-size copper particles and the CTE modifier.

13. The PCB of claim 11, wherein the copper composite has a uniform nanoporosity of about 2% to about 30%.

14. The PCB of claim 11, wherein the at least one heat spreader is bonded to the heat-producing component via a bonding layer comprising a second copper composite that is CTE-matched to the heat-producing component.

15. The PCB of claim 14, wherein the second copper composite of the bonding layer has a uniform nanoporosity of about 2% to about 30%.

16. The PCB of claim 11, wherein the CTE modifier comprises particles or fibers selected from the group consisting of carbon, W, Mo, diamond, boron nitride, aluminum nitride, silicon nitride, carbon nanotubes, graphene, graphite, copper oxide nanoparticles, and any combination thereof.

17. The PCB of claim 11, wherein the thermally conductive body is wholly formed from the copper composite comprising the CTE modifier.

18. The PCB of claim 17, wherein the CTE modifier is distributed throughout the thermally conductive body.

19. The PCB of claim 11, wherein the thermally conductive body is tapered.

20. The PCB of claim 11, wherein the heat-producing component is located upon or recessed within a surface of the electrically insulating substrate, and:
the at least one heat spreader is bonded to a top surface of the heat-producing component,
the at least one heat spreader is bonded to a side surface of the heat-producing component,
the at least one heat spreader is bonded to a bottom surface of the heat-producing component and the at least one heat spreader extends through the electrically insulating substrate,
or any combination thereof.

21. The PCB of claim 11, wherein the CTE modifier is present in the copper composite in a stepwise or gradient concentration distribution.

22. The PCB of claim 11, wherein the copper composite has a CTE of about 3 ppm to about 7 ppm.

23. A heat dissipation system comprising:
a heat spreader having a thermally conductive body, in which at least a portion of the thermally conductive body or a coating thereon comprises a copper composite that comprises a coefficient of thermal expansion (CTE) modifier, such that the thermally conductive body has a CTE of about 3 ppm to about 7 ppm;
a heat-producing component in contact with a first surface of the thermally conductive body, the heat-producing component having a CTE of about 3 ppm to about 7 ppm; and
a heat sink or a heat pipe in contact with a second surface of the thermally conductive body;
wherein the heat sink or the heat pipe is also formed from the copper composite comprising the coefficient of thermal expansion modifier and has a CTE of about 3 to about 7 ppm.

24. The heat dissipation system of claim 23, wherein the thermally conductive body or the coating thereon is metallurgically bonded to the heat sink or the heat pipe via a bonding layer.

25. The heat dissipation system of claim 23, wherein the thermally conductive body or the coating thereon has a CTE within about +20% of the heat-producing component.
